(19) United States
(12) Patent Application Publication
(10) Pub. No.: US 2012/0132914 A1
(43) Pub. Date: May 31, 2012

(54) OXIDE SEMICONDUCTOR THIN FILM TRANSISTOR STRUCTURE AND METHOD OF MAKING THE SAME

(76) Inventors: Chia-Hsiang Chen, Hsin-Chu (TW); Shih-Hsien Tseng, Hsin-Chu (TW); Ming-Chin Hung, Hsin-Chu (TW); Chun-Hao Tu, Hsin-Chu (TW); Wei-Ting Lin, Hsin-Chu (TW); Jiun-Jye Chang, Hsin-Chu (TW)

(21) Appl. No.: 13/045,502

(22) Filed: Mar. 10, 2011

(30) Foreign Application Priority Data
Nov. 30, 2010 (TW) 099141626

(51) Int. Cl. H01L 29/786; H01L 21/336

(52) U.S. Cl. 257/57; 438/158; 257/E29.273; 257/E21.412

(57) ABSTRACT

An oxide semiconductor thin film transistor structure includes a substrate, a gate electrode disposed on the substrate, a semiconductor insulating layer disposed on the substrate and the gate electrode, an oxide semiconductor layer disposed on the semiconductor insulating layer, a patterned semiconductor layer disposed on the oxide semiconductor layer, and a source electrode and a drain electrode respectively disposed on the patterned semiconductor layer. The source electrode and the drain electrode are made of a metal layer.

### BACKGROUND OF THE INVENTION

1. Field of the Invention

The present invention relates to an oxide semiconductor thin film transistor structure and a method of making the same, and more particularly, to an oxide semiconductor thin film transistor structure having a patterned semiconductor layer and a method of making the same.

2. Description of the Prior Art

Recently, oxide semiconductors are utilized as an alternative choice for serving as channels of thin film transistors in replace of silicon channels of conventional thin film transistors. Oxide semiconductor thin film transistors have high carrier mobility as low temperature polycrystalline silicon thin film transistors and high electrical uniformity as amorphous silicon thin film transistors. Therefore, liquid crystal display devices adopting the oxide semiconductor thin film transistors have gradually become mainstream products on the market.

Please refer to FIG. 1, which schematically illustrates a cross-sectional view of a conventional oxide semiconductor thin film transistor structure. As shown in FIG. 1, the conventional oxide semiconductor thin film transistor structure 10 includes a substrate 11, a gate electrode 12 disposed on the substrate 11, a semiconductor insulating layer 13 disposed on the substrate 11 and the gate electrode 12, an oxide semiconductor layer 14 disposed on the semiconductor insulating layer 13, a source electrode 151 and a drain electrode 152 respectively disposed on the oxide semiconductor layer 14. In addition, the source electrode 151 and the drain electrode 152 are formed by performing an etching process on a metal layer. However, in the etching process for forming the source electrode 151 and the drain electrode 152 of the conventional oxide semiconductor thin film transistor structure 10, the oxide semiconductor layer 14 disposed below the source electrode 151 and the drain electrode 152 tends to be corroded by etching solution for etching metal. Thus, the oxide semiconductor layer 14 would be broken or have poor subthreshold swings (S.S). Therefore, the corrosion problem of the oxide semiconductor layer 14 of the conventional oxide semiconductor thin film transistor structure 10 due to the metal etching solution needs to be improved.

### SUMMARY OF THE INVENTION

It is therefore one of the objectives of the present invention to provide an oxide semiconductor thin film transistor structure having a patterned semiconductor layer to protect the oxide semiconductor layer from being corroded by the metal etching liquid, and also to obtain a lower resistance for forming an ohmic contact so as to promote electrical properties.

In accordance with a preferred embodiment of the present invention, an oxide semiconductor thin film transistor structure includes a substrate, a gate electrode disposed on the substrate, a semiconductor insulating layer disposed on the substrate and the gate electrode, an oxide semiconductor layer disposed on the semiconductor insulating layer, a patterned semiconductor layer disposed on the oxide semiconductor layer, a source electrode and a drain electrode respectively disposed on the patterned semiconductor layer. In addition, the source electrode and the drain electrode are made of a metal layer.

In accordance with the preferred embodiment of the present invention, a method of forming the oxide semiconductor thin film transistor structure is described as followed. A substrate is provided. A gate electrode is formed on the substrate. A semiconductor insulating layer is formed on the gate electrode. An oxide semiconductor layer is formed on the semiconductor insulating layer. A semiconductor layer is formed on the oxide semiconductor layer. A metal layer is formed on the semiconductor layer. A source electrode and a drain electrode are formed by performing a wet etching process to remove a part of the metal layer, so that a part of the semiconductor layer is consequently exposed. A patterned semiconductor layer is formed by removing of the part of the semiconductor layer exposed by the source electrode and the drain electrode.

In accordance with the method of forming the oxide semiconductor thin film transistor structure of the present invention, a patterned semiconductor layer is additionally disposed between the oxide semiconductor layer and the metal layer to protect the oxide semiconductor layer from being corroded by the metal etching solution, and also to obtain a lower resistance for forming an ohmic contact so as to promote electrical properties. Moreover, no extra mask is required since the patterned semiconductor layer can be patterned along with the etching process used to pattern the source electrode and the drain electrode.

To provide a better understanding of the presented invention for esteemed examiners, please refer to the following elaborations and the accompanying drawings related to the present invention. It is noted that all drawings are not to limit the present invention.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a cross-sectional view of a conventional oxide semiconductor thin film transistor structure.

FIG. 2 is a schematic diagram illustrating a cross-sectional view of an oxide semiconductor thin film transistor structure according to a preferred embodiment of the present invention.

FIG. 3 through FIG. 10 are schematic diagrams illustrating a method of forming the oxide semiconductor thin film transistor structure according to a preferred embodiment of the present invention.

FIG. 11 is a characteristic diagram illustrating relations between drain current and gate voltage under different drain voltages of the oxide semiconductor thin film transistor structure of the present invention.

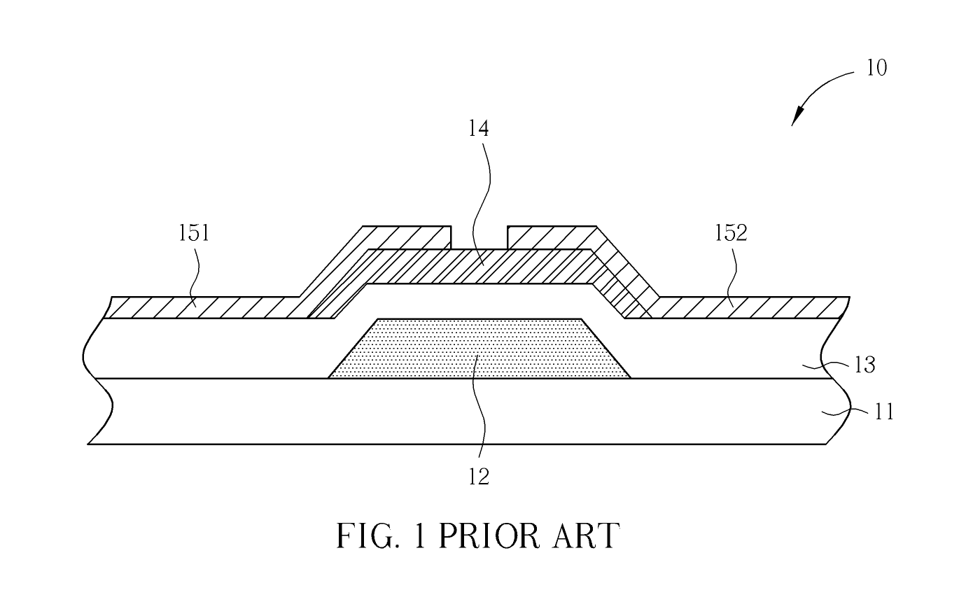

### DETAILED DESCRIPTION

To provide a better understanding of the presented invention for one skilled in the art, a preferred embodiment will be detailed as follows. The preferred embodiments of the present invention are illustrated in the accompanying drawings with numbered elements to elaborate the contents and effects to be achieved.

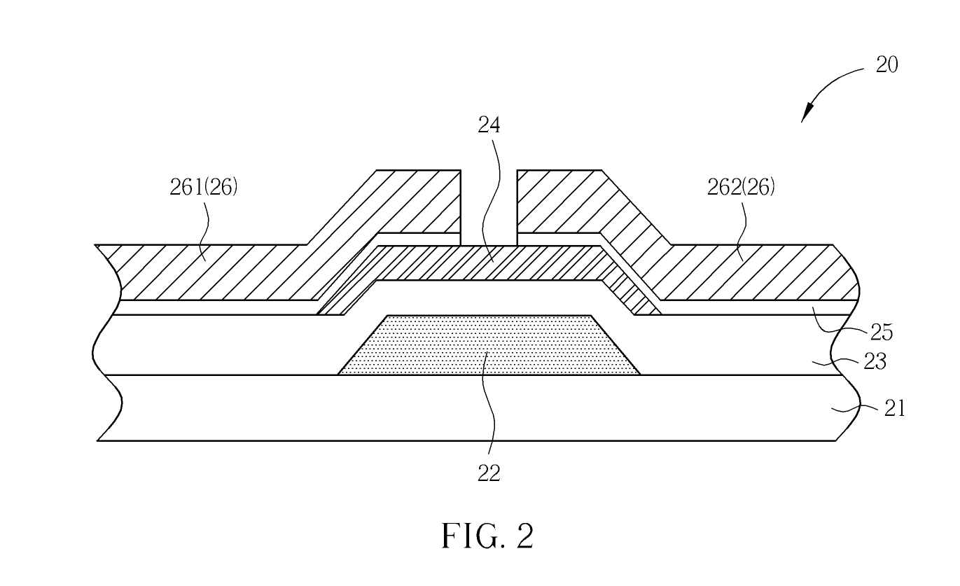

Please refer to FIG. 2, which schematically illustrates a cross-sectional view of an oxide semiconductor thin film transistor structure according to a preferred embodiment of the present invention. As shown in FIG. 2, the oxide semiconductor thin film transistor structure 20 includes a substrate 21, a gate electrode 22 disposed on the substrate 21, a semiconductor insulating layer 23 disposed on the substrate 21 and the gate electrode 22, an oxide semiconductor layer 24 disposed on the semiconductor insulating layer 23, a patterned semiconductor layer 25 disposed on the oxide semiconductor layer 24, a source electrode 261 and a drain electrode 262 respectively disposed on the patterned semiconductor layer 25. In addition, the source electrode 261 and the drain electrode 262 are made of a metal layer 26. In this embodiment, the oxide semiconductor layer 24 can be an indium gallium zinc oxide layer, but not limited thereto. For example, the oxide semiconductor layer 24 also can include indium, zinc, tin, gallium, lead, germanium, cadmium, or an oxide compound thereof, such as indium zinc oxide and zinc tin oxide, but not limited thereto.

In this preferred embodiment, the patterned semiconductor layer 25 is able to protect the oxide semiconductor layer 24 thereunder, for example, against a wet etching process. Meanwhile, the oxide semiconductor layer 24 disposed below the patterned semiconductor layer 25 is able to obtain better properties of semiconductor by adjusting a volume flux of gases, such as the volume flux of argon, phosphorus trihydride, and silicon tetrahydride, when forming the patterned semiconductor layer 25. In this preferred embodiment, the patterned semiconductor layer 25 can be a doped amorphous silicon layer, an undoped amorphous silicon layer, a doped microcrystalline silicon layer or an undoped microcrystalline silicon layer, but not limited thereto. It is noted that a choice of the patterned semiconductor layer 25 is related to a material of the metal layer 26, disposed on the patterned semiconductor layer 25, for forming the source electrode 261 and the drain electrode 262. On condition that the patterned semiconductor layer 25 is a doped semiconductor layer, such as the doped amorphous silicon layer, the metal layer 26 can be a single-layered metal layer, made of a material including aluminum, molybdenum, titanium, chromium, an alloy thereof or a compound thereof. Also, the metal layer 26 can be a composite-layered metal layer, and materials of the composite-layered metal layer include at least two of aluminum, molybdenum, titanium, chromium, alloys thereof or compounds thereof. Otherwise, on condition that the patterned semiconductor layer 25 is an undoped semiconductor layer, such as the undoped amorphous silicon layer, the metal layer 26 can be a single-layered metal layer, made of a material including copper or a copper alloy; and also the metal layer 26 can be a composite-layered metal layer, made of a composite material including copper or a copper alloy. In other words, when at least one of the materials, such as aluminum, molybdenum, titanium, chromium, an alloy thereof and a compound thereof, is chosen for forming the metal layer 26, the patterned semiconductor layer 25 is preferably the doped semiconductor layer. Alternatively, when at least one of the materials, such as copper or a copper alloy, is chosen for forming the bottom of the metal layer 26 that contacts the patterned semiconductor layer 25, the patterned semiconductor layer 25 is preferably the undoped semiconductor layer, such as the undoped amorphous semiconductor layer. Additionally, a thickness of the patterned semiconductor layer 25 is substantially between 10 nanometers and 30 nanometers, and a preferred thickness is about 20 nanometers, but not limited thereto.

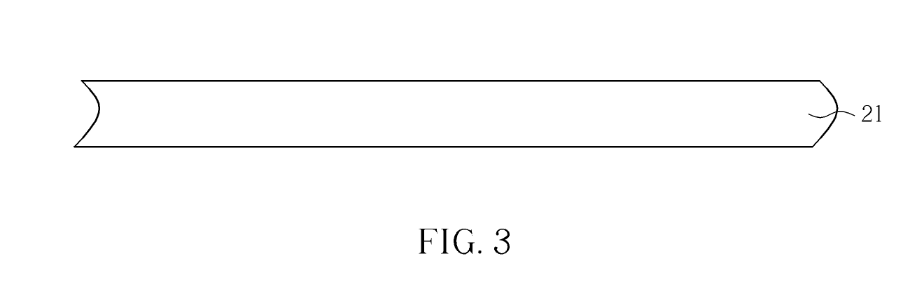

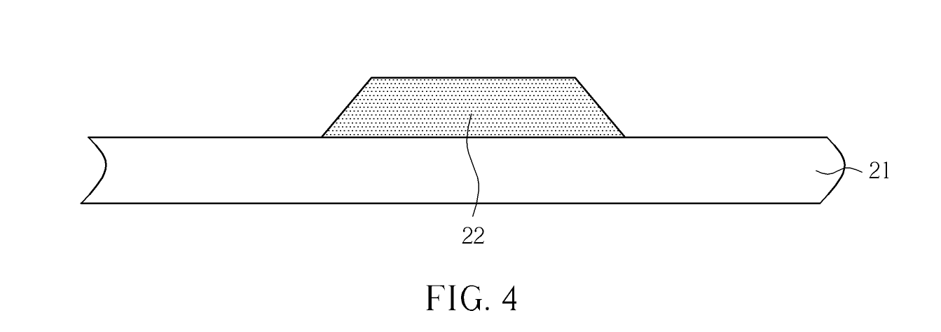

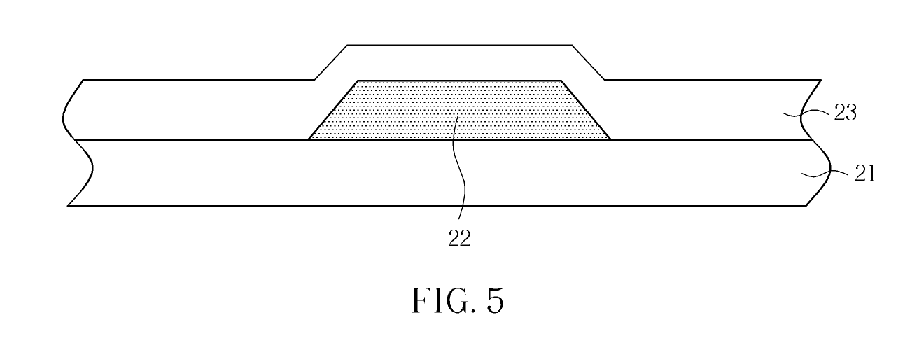

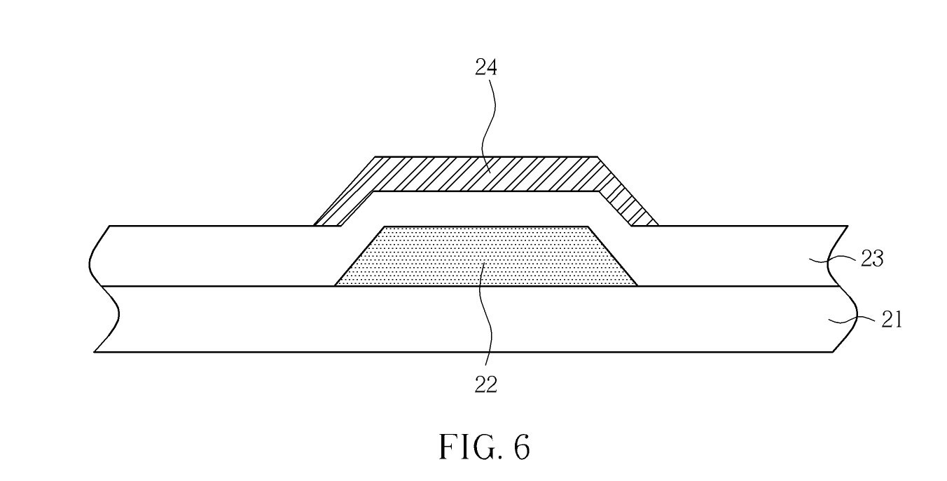

Please refer to FIG. 3 through FIG. 10, which schematically illustrate a method of forming the oxide semiconductor thin film transistor structure according to a preferred embodiment of the present invention. As shown in FIG. 3, a substrate 21 is provided. As shown in FIG. 4, a metal layer is formed on the substrate 21, and a gate electrode 22 is formed by, for instance, performing a photolithography and etching process on the metal layer, but not limited thereto. As shown in FIG. 5, a semiconductor insulating layer 23 is formed on the substrate 21 and the gate electrode 22. As shown in FIG. 6, an oxide semiconductor layer 24 is formed on the semiconductor insulating layer 23. According to this preferred embodiment, the oxide semiconductor layer 24 is formed by performing a vacuum sputtering process to deposit an indium gallium zinc oxide layer on the semiconductor insulating layer 23, but not limited thereto. For example, the oxide semiconductor layer 24 also can be made of an oxide material including indium, zinc, tin, gallium, lead, germanium, cadmium, or an oxide compound thereof, such as indium zinc oxide and zinc tin oxide, but not limited thereto. Additionally, in this preferred embodiment, the oxide semiconductor layer 24 is deposited on the semiconductor insulating layer 23 by performing a vacuum sputtering process, but not limited thereto. The oxide semiconductor layer 24 also can be formed on the semiconductor insulating layer 23 by, for example, coating a liquid, or by other processes.

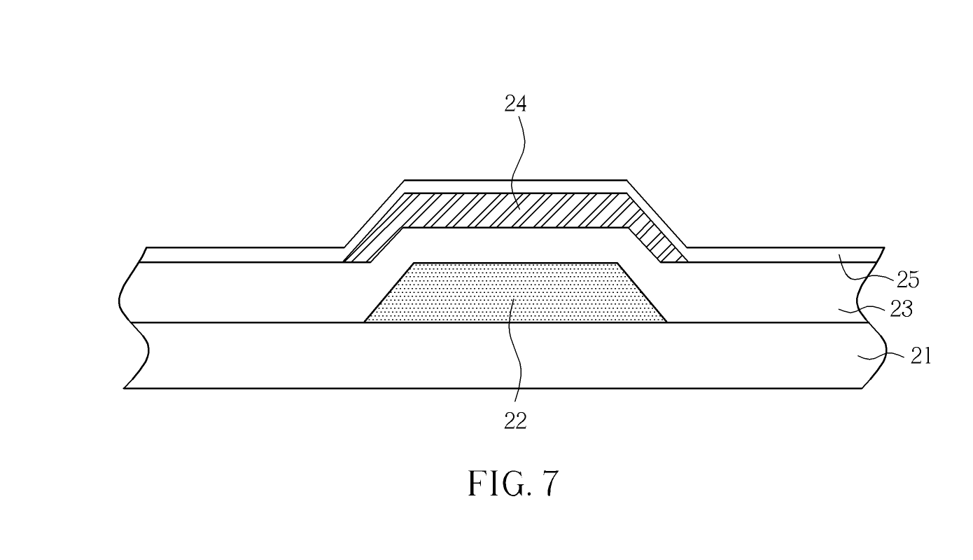

As shown FIG. 7, a semiconductor layer 25 is formed on the oxide semiconductor layer 24 by performing a vacuum deposition process. In this preferred embodiment, a step of forming the semiconductor layer 25 includes introducing a gas mixture including inert gas such as argon, and phosphorus trihydride and silicon tetrahydride. A ratio of a volume flux of argon to a total volume flux of phosphorus trihydride and silicon tetrahydride is preferably substantially larger than or equal to 5. For instance, the volume flux of argon is about 750 standard cubic centimeter per minute (sccm), the volume flux of the phosphorus trihydride is about 80 standard cubic centimeter per minute (sccm), and the volume flux of silicon tetrahydride is about 50 standard cubic centimeter per minute (sccm), but not limited thereto. It is noted that the purpose of introducing inert gas such as argon, is to dilute a concentration of hydrogen atoms so as to reduce a dosage of hydrogen doping when the semiconductor layer 25 is formed. Also, O—H bonds tend to be formed by the hydrogen atoms and oxygen atoms within the oxide semiconductor layer 24, so that an oxygen deficient area within the oxide semiconductor layer 24 can be reduced. As a result, the oxide semiconductor layer 24 is able to obtain better properties of semiconductor, such as high carrier mobility and high electrical uniformity. Also, in this preferred embodiment, the semiconductor layer 25 can be a doped semiconductor layer or an undoped semiconductor layer by adjusting the volume flux of phosphorus trihydride. For example, when phosphorus trihydride is not introduced in the process, the semiconductor layer 25 will become an undoped semiconductor layer. In this case, a ratio of the volume flux of argon to the volume flux of silicon tetrahydride is preferably substantially larger than or equal to 5. Moreover, as previously mentioned, the material for forming the semiconductor layer 25 can be chosen according to the material of the source electrode and the drain electrode to be formed subsequently.

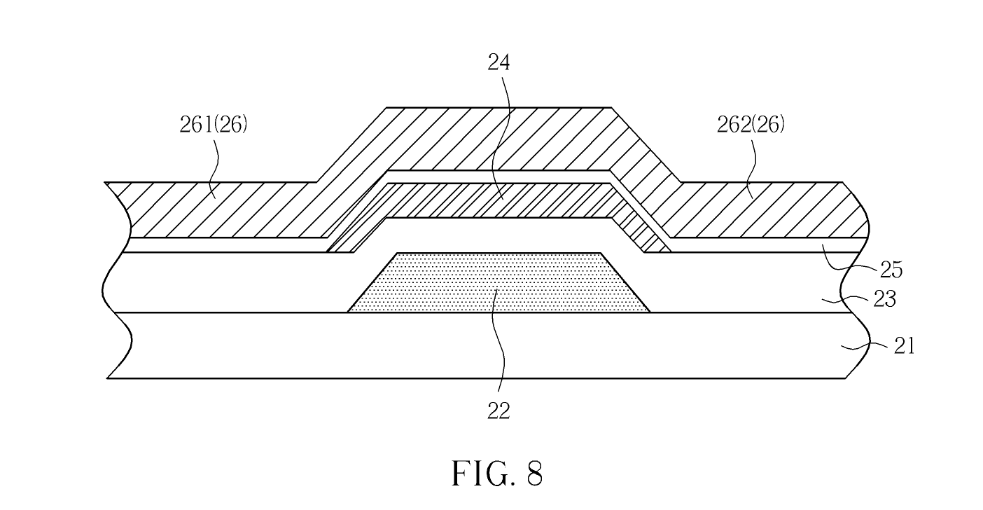

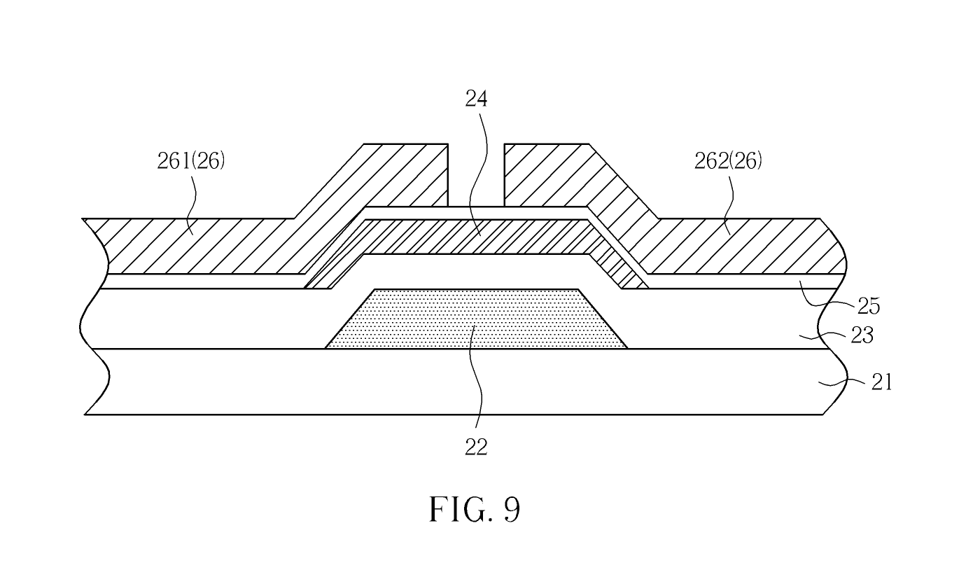

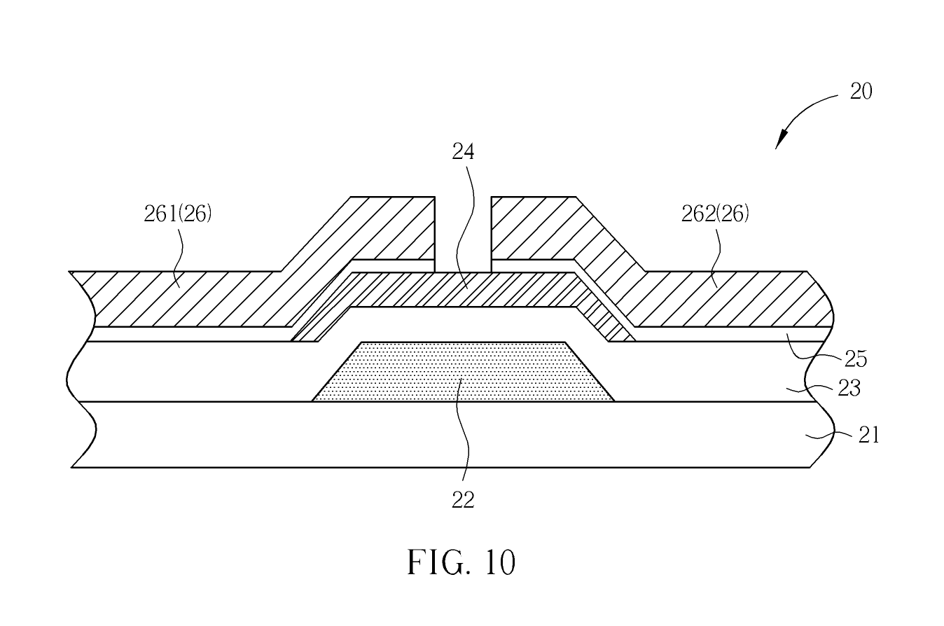

As shown in FIG. 8, a metal layer 26 is formed on the semiconductor layer 25. In this preferred embodiment, the metal layer for forming the gate electrode 22 and the metal layer 26 can be a single-layered metal layer made of a material including aluminum, molybdenum, titanium, chromium, copper, and an alloy thereof or a compound thereof respectively; and also the metal layer for forming the gate electrode 22 and the metal layer 26 can be a composite-layered metal layer, and materials of the composite-layered metal layer include at least two of aluminum, molybdenum, titanium, chromium, alloys thereof or compounds thereof respectively. As shown in FIG. 9, the source electrode 261 and the drain electrode 262 are formed by performing a wet etching process to remove a part of the metal layer 26 and to expose a part of the semiconductor layer 25. As shown in FIG. 10, in this preferred embodiment, the patterned semiconductor layer 25 is formed by performing a dry etching process to remove the part of the semiconductor layer 25 exposed by the source electrode 261 and the drain electrode 262. Thus, the oxide semiconductor thin film transistor structure 20 according to this preferred embodiment is accomplished.

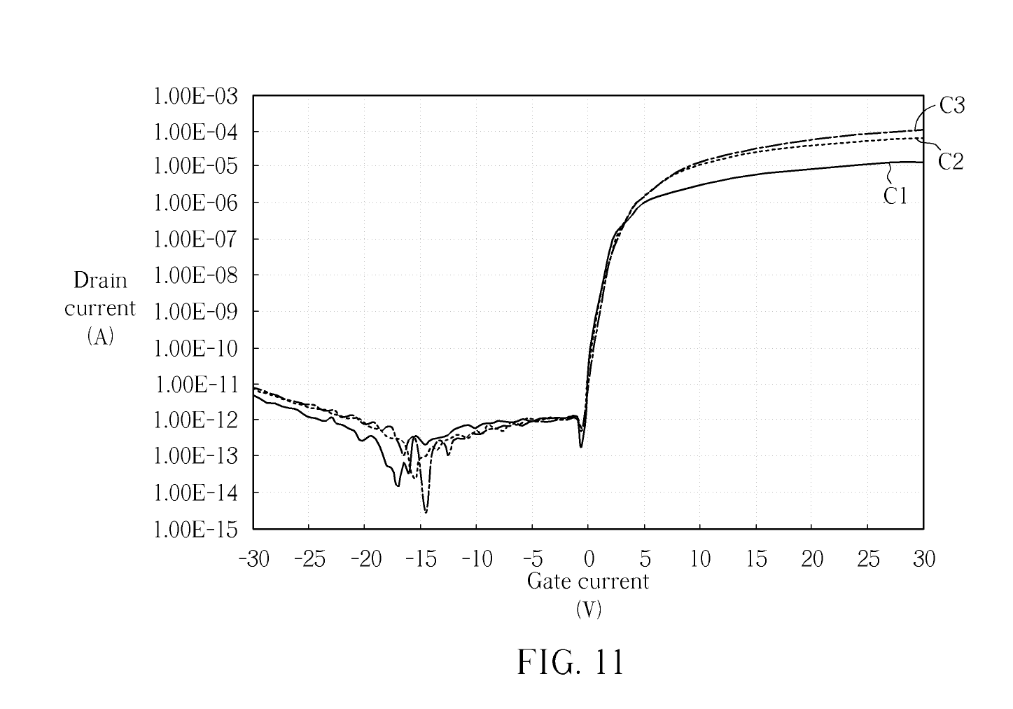

Please refer to FIG. 11, which is a characteristic diagram illustrating relations between drain current (Id) and gate voltage (Vg) under different drain voltages (Vd) of the oxide semiconductor thin film transistor structure of the present invention. As shown in FIG. 11, curves C1, C2, and C3 illustrate a relation between the drain currents and the corresponding gate voltages when the drain voltage of about 1, 5, and 9 volts is provided respectively. As shown by the curve C1, on condition that the drain voltage of about 1 volt is provided, a drain current of about 1×10⁻⁵ amperes can be obtained. Moreover, the drain current tends to increase with an increase of the provided drain voltage. For instance, as shown by curve C2, on condition that a drain voltage of about 5 volts is provided, the drain current tends to increase prominently; as shown by the curve C3, on condition that a drain voltage of about 9 volts is provided, the drain current can reach to about 1×10⁻⁴ amperes. As a result, it can be proven that the oxide semiconductor thin film transistor structure according to the method in the present invention is capable of forming an ohmic contact between the pattern semiconductor layer and the oxide semiconductor layer, so that the drain current can be increased, and the electron mobility can reach to about 10.25 cm²/Vs.

To sum up, according to the oxide semiconductor thin film transistor structure of the present invention, a patterned semiconductor layer is additionally disposed between the metal layer forming the source electrode and the drain electrode, and the oxide semiconductor layer. The patterned semiconductor layer and the oxide semiconductor layer are able to form the ohmic contact by adjusting the ratio of the volume flux of gases introduced for forming the patterned semiconductor layer. Accordingly, the oxide semiconductor layer is protected from being corroded by the etching solution. Also, the patterned semiconductor layer is capable of enhancing a uniformity of the dry etching process so as to promote electrical properties of the oxide semiconductor thin film transistor structure.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An oxide semiconductor thin film transistor structure, comprising:
a substrate;
a gate electrode, disposed on the substrate;
a semiconductor insulating layer, disposed on the substrate and the gate electrode;
an oxide semiconductor layer, disposed on the semiconductor insulating layer;
a patterned semiconductor layer, disposed on the oxide semiconductor layer; and
a source electrode and a drain electrode, disposed on the patterned semiconductor layer, wherein the source electrode and the drain electrode are made of a metal layer.

2. The oxide semiconductor thin film transistor structure according to claim 1, wherein a material of the oxide semiconductor layer includes indium zinc oxide, indium gallium zinc oxide or zinc tin oxide.

3. The oxide semiconductor thin film transistor structure according to claim 1, wherein the patterned semiconductor layer comprises a doped semiconductor layer.

4. The oxide semiconductor thin film transistor structure according to claim 3, wherein the doped semiconductor layer includes a doped amorphous silicon layer or a doped microcrystalline silicon layer.

5. The oxide semiconductor thin film transistor structure according to claim 3, wherein the metal layer forming the source electrode and the drain electrode includes a single-layered metal layer or a composite-layered metal layer.

6. The oxide semiconductor thin film transistor structure according to claim 5, wherein a material of the single-layered metal layer includes aluminum, molybdenum, titanium, chromium, an alloy thereof or a compound thereof; and materials of the composite-layered metal layer include at least two of aluminum, molybdenum, titanium, chromium, alloys thereof or compounds thereof.

7. The oxide semiconductor thin film transistor structure according to claim 1, wherein the patterned semiconductor layer comprises an undoped semiconductor layer.

8. The oxide semiconductor thin film transistor structure according to claim 7, wherein the undoped semiconductor layer comprises an undoped amorphous silicon layer or an undoped microcrystalline silicon layer.

9. The oxide semiconductor thin film transistor structure according to claim 7, wherein the metal layer forming the source electrode and the drain electrode includes a single-layered metal layer or a composite-layered metal layer.

10. The oxide semiconductor thin film transistor structure according to claim 9, wherein a material of the single-layered metal layer includes copper or a copper alloy; and a material of a bottom of the composite-layered metal layer includes copper or a copper alloy.

11. A method of forming an oxide semiconductor thin film transistor structure, comprising:
providing a substrate;
forming a gate electrode on the substrate;
forming a semiconductor insulating layer on the gate electrode;
forming an oxide semiconductor layer on the semiconductor insulating layer;
forming a semiconductor layer on the oxide semiconductor layer;
forming a metal layer on the semiconductor layer;
removing a part of the metal layer by performing a wet etching process for forming a source electrode and a drain electrode and exposing a part of the semiconductor layer; and
removing the part of semiconductor layer exposed by the source electrode and the drain electrode for forming a patterned semiconductor layer.

12. The method of forming the oxide semiconductor thin film transistor structure according to claim 11, wherein the patterned semiconductor layer includes a doped amorphous silicon layer or a doped microcrystalline silicon layer.

13. The method of forming the oxide semiconductor thin film transistor structure according to claim 12, wherein a step of forming the semiconductor layer includes introducing a gas mixture comprising argon, phosphorus trihydride, and silicon tetrahydride, wherein a ratio of a volume flux of argon to a total volume flux of phosphorus trihydride and silicon tetrahydride is substantially larger than or equal to 5.

14. The method of forming the oxide semiconductor thin film transistor structure according to claim 11, wherein the patterned semiconductor layer includes an undoped amorphous silicon layer or an undoped microcrystalline silicon layer.

15. The method of forming the oxide semiconductor thin film transistor structure according to claim 14, wherein a step of forming the semiconductor layer includes introducing a gas mixture comprising argon and silicon tetrahydride, wherein a ratio of a volume flux of argon to a volume flux of silicon tetrahydride is substantially larger than or equal to 5.

16. The method of forming the oxide semiconductor thin film transistor structure according to claim 11, wherein a step of removing the part of semiconductor layer exposed by the source electrode and the drain electrode for forming the patterned semiconductor layer is achieved by performing a dry etching process.
